(19) United States
(12) Patent Application Publication
(10) Pub. No.: US 2011/0188299 A1
(43) Pub. Date: Aug. 4, 2011

(54) DATA STORAGE DEVICE

(76) Inventor: Derek Atkinson, Durham (GB)

(21) Appl. No.: 13/063,249

(22) PCT Filed: Aug. 25, 2009
(86) PCT No.: PCT/GB09/51058

§ 371 Date: Apr. 13, 2011

(30) Foreign Application Priority Data
Sep. 12, 2008 (GB) 0816640.7

(51) Int. Cl. G11C 11/15

(52) U.S. Cl. 365/158

(57) ABSTRACT

A data storage device (2) comprising a plurality of stacked layers (4) of memory cells (6) is disclosed. Each memory cell comprises a first magnetic layer (5), including an elongate curved portion (10), and a second magnetic layer. The first magnetic layer is adapted to be selectively magnetised to adopt one of a plurality of possible magnetised states, wherein the electrical resistance between the first magnetic layer and the second magnetic layer has a magnitude dependent upon the magnetised state of said first magnetic layer. Switching means is adapted to cause the first magnetic layer to switch between magnetised states thereof.

The present invention relates to data storage devices, and relates particularly, but not exclusively, to high density magnetoresistive data storage devices.

US 2006/0221677 discloses a data storage device having an array of memory cells in which each memory cell includes a linear element of magnetic material which is capable of being selectively magnetised to a plurality of magnetised states. The electrical resistance of the magnetic elements is dependent upon the magnetised state, and the magnetised states of the memory cells can therefore be used to represent binary bits of data.

However, this known arrangement suffers from the drawback that the energy required to write data to the memory cells (and therefore the power consumed by the data storage device as a whole) is large, and it is difficult to write data to one memory cell while avoiding changing the state of neighbouring memory cells to the cell of interest (known as the half select problem). Also, the elongated linear geometry of existing memory devices of this type gives rise to difficulties in achieving a high spatial packing density.

Preferred embodiments of the present invention seek to overcome one or more of the above disadvantages of the prior art.

According to the present invention, there is provided a data storage device comprising:

at least one memory cell comprising at least one respective first magnetic layer including at least one elongate curved portion having respective first and second ends;

at least one second magnetic layer, wherein at least one said first magnetic layer is adapted to be selectively magnetised to adopt one of a plurality of possible magnetised states, wherein the electrical resistance between said first magnetic layer and at least one said second magnetic layer has a magnitude dependent upon the magnetised state of said first magnetic layer; and

switching means adapted to cause at least one said first magnetic layer to switch between magnetised states thereof.

By providing at least one memory cell comprising at least one respective first magnetic layer including at least one elongate curved portion having respective first and second ends, this provides the advantage of more closely matching the geometry of the magnetizable components of the storage device to the geometry of the magnetic fields generated in the storage device in order to write data to the memory cells. In particular, the curved elongated structures of the present invention enable each memory cell to be constructed more compactly, which in turn enables array packing density to be improved, and which in turn reduces the size of the device. The amount of energy required to write data to the device is also reduced by reducing generation of magnetic fields outside of the regions in which they are required, which therefore reduces the power consumption of the device. Also, by more closely matching the geometries of the components to the magnetic fields generated to reduce generation of magnetic fields outside of the regions in which they are required, the half select problem is reduced.

At least one said elongate curved portion may be partially annular.

By providing a partially annular elongate curved portion, this provides the advantage of improving the degree of control with which magnetised states of the curved portion can be induced.

At least one said first magnetic layer may be adapted to be magnetised such that at least one said curved portion thereof is magnetised predominately along a single direction in at least one said magnetised state thereof.

In a preferred embodiment, at least one said elongate curved portion is adapted to be magnetised such that said curved portion includes (i) a plurality of regions, wherein the regions of each pair of adjacent said regions are magnetised predominately along different directions and are separated by a respective magnetic domain wall, and (ii) at least one first structural feature adapted to prevent propagation of at least one said magnetic domain wall of a first type past said first structural feature.

By providing at least one said elongate curved portion adapted to be magnetised such that said curved portion includes a plurality of regions separated by a magnetic domain wall, and at least one first structural feature adapted to prevent propagation of at least one magnetic domain wall of a first type past the first structural feature, this provides the advantage of increasing the number of magnetisation states of each memory cell, which increases the number of data bits which can be stored by each memory cell and therefore increases the density with which data can be stored by the storage device as a whole.

At least one said elongate curved portion may be adapted to be magnetised such that said curved portion includes (iii) at least one second structural feature adapted to prevent propagation of at least one said magnetic domain wall of a second type past said second structural feature.

At least one said second structural feature may be a notch in or protrusion on the corresponding said elongate curved portion.

At least one said first structural feature may be a notch in or protrusion in the corresponding said elongate curved portion.

At least one said first and/or second structural feature may be located on an edge of a corresponding said elongate curved portion.

At least one said first magnetic layer may include an end portion having larger width than the adjacent said elongate curved portion.

By providing an end portion having larger width than the adjacent said elongate curved portion, this provides the advantage of assisting generation of magnetic domain walls when data is written to the device.

Said switching means may comprise at least one first electrical conductor adapted to generate at least one first magnetic field and passing through at least one said memory cell, and at least one second electrical conductor adapted to generate at least one second magnetic field and arranged adjacent at least one said memory cell.

At least one said first electrical conductor may be substantially surrounded by said elongate curved portion of at least one said memory cell.

This provides the advantage of closely matching the geometry of the components of the memory cell the geometry of the magnetic field generated by the first electrical conductor, which in turn reduces the size and power consumption of the data storage device.

The device may comprise at least one array of said memory cells.

At least one said array may include at least one said second conductor arranged adjacent a plurality of said memory cells of said array such that at least one said second magnetic field interacts with at least one said first magnetic field generated by at least one said first conductor to change the magnetised state of a said elongate curved portion.

The device may further comprise a plurality of said arrays, wherein at least one said first conductor extends through a plurality of arrays.

This provides the advantage of increasing the density with which data can be stored.

A plurality of said memory cells of at least one said array may be arranged in a substantially hexagonal formation.

This provides the advantage of increasing the density of storage.

The device may further comprise means for measuring electrical resistance between at least one said first magnetic layer and a said second magnetic layer.

Preferred embodiments of the invention will now be described, by way of example only and not in any limitative sense, with reference to the accompanying drawings, in which:

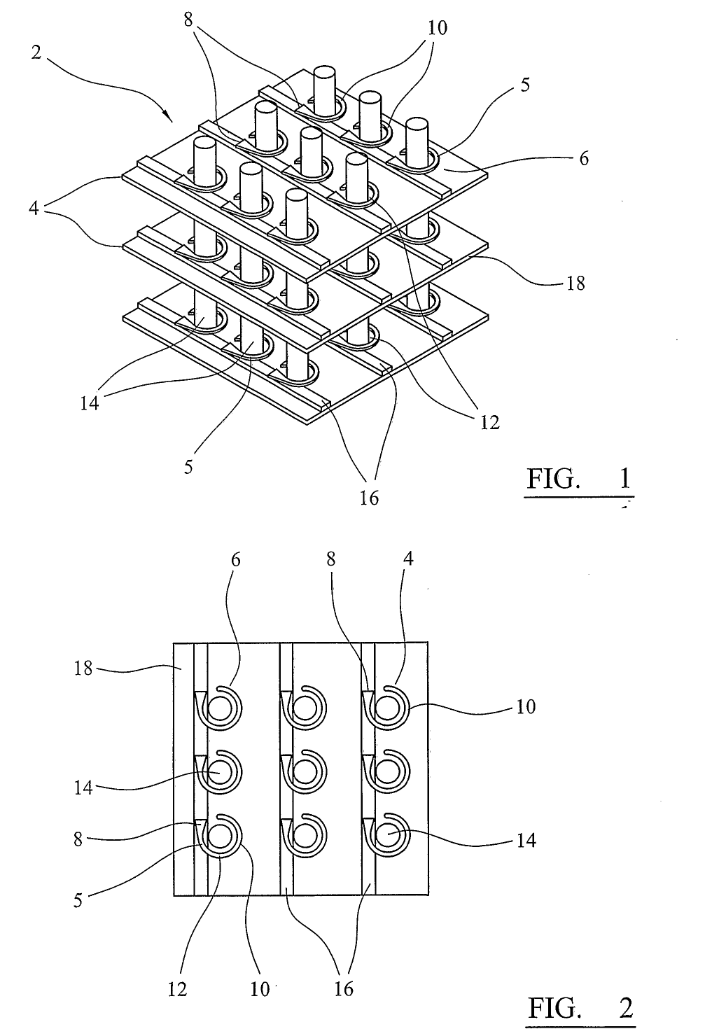

FIG. 1 is a schematic perspective view of a data storage device of a first embodiment of the present invention;

FIG. 2 is a plan view of the data storage device of FIG. 1;

FIG. 3 is a schematic view of a device for reading data from a data cell of the data storage device of FIG. 1;

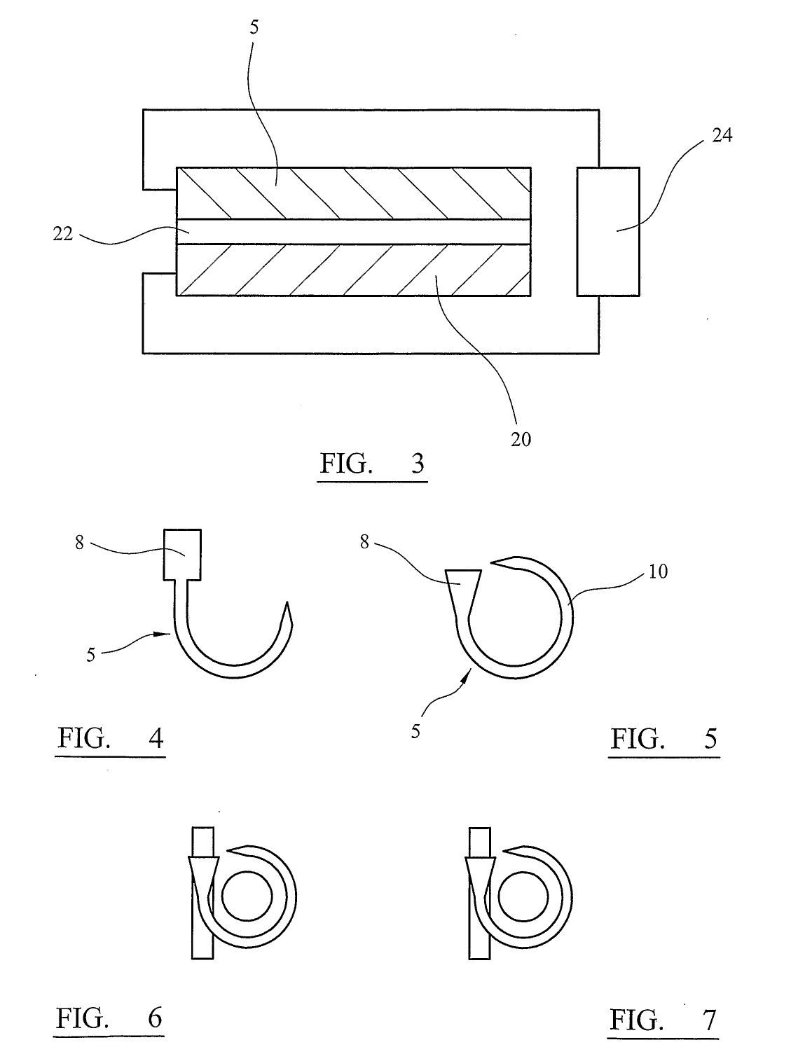

FIG. 4 is a plan view of a first embodiment of a memory cell used in the data storage device of FIG. 1;

FIG. 5 is a plan view of a second embodiment of a memory cell used in the data storage device of FIG. 1;

FIG. 6 shows a first magnetised state of the data cell of FIG. 5;

FIG. 7 shows a second magnetised state of the data cell of FIG. 5;

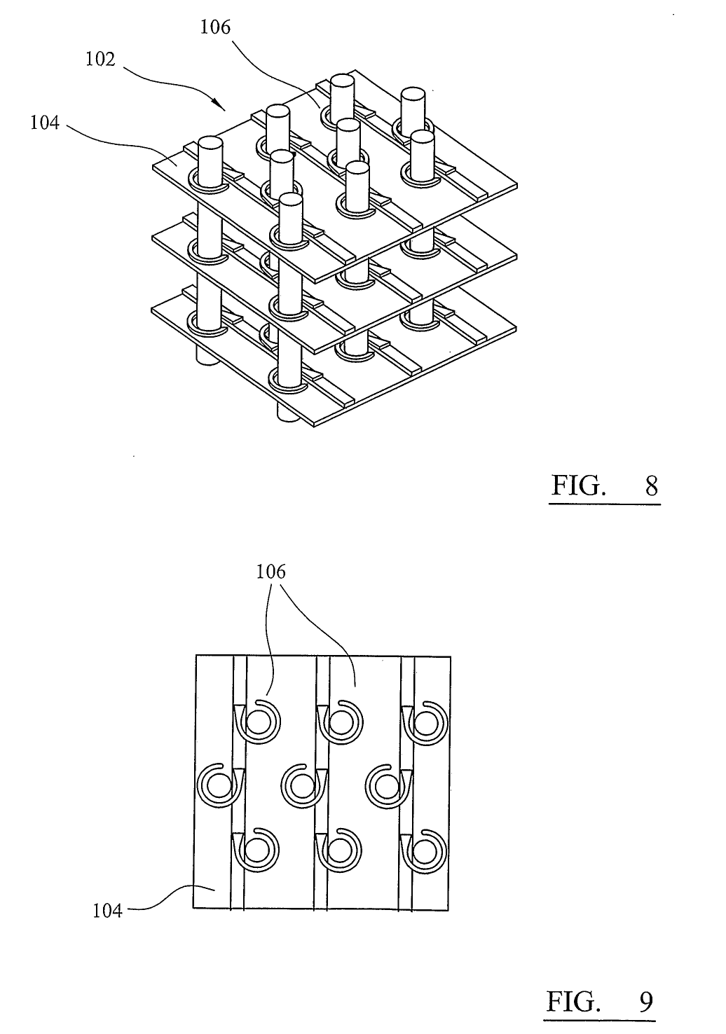

FIG. 8 is a schematic perspective view of a data storage device of a second embodiment of the present invention;

FIG. 9 is a plan view of the data storage device of FIG. 8;

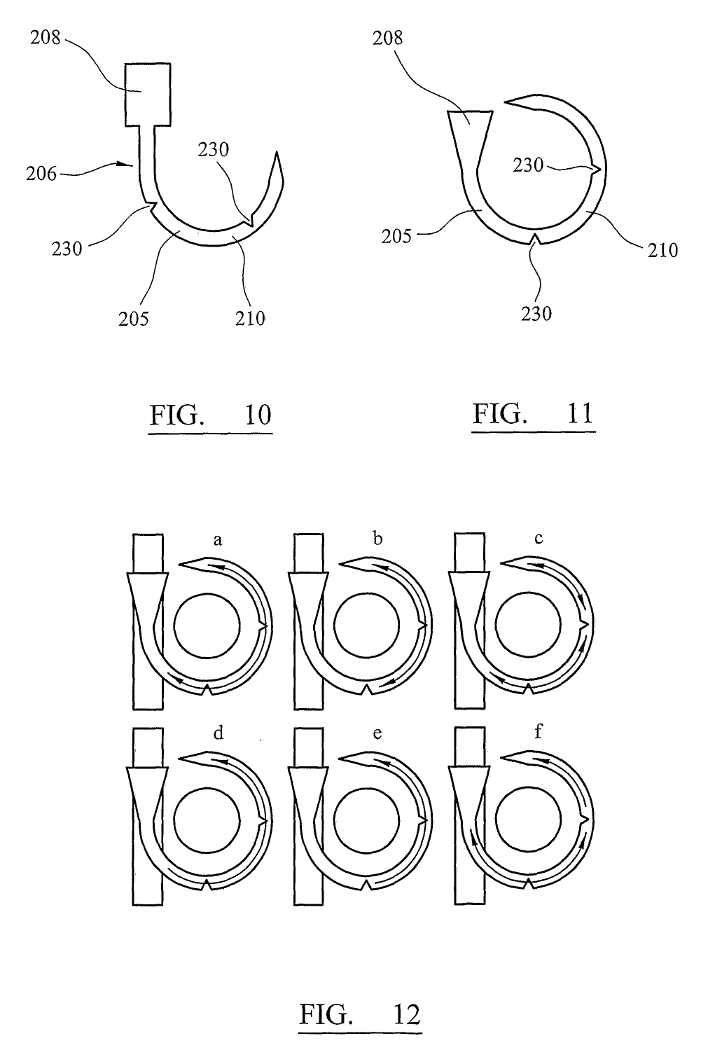

FIG. 10 is a plan view of a third embodiment of a memory cell used in the data storage device of FIG. 1;

FIG. 11 is a plan view of a fourth embodiment of a memory cell used in the data storage device of FIG. 1; and

FIG. 12 shows six possible magnetisation states of the memory cell of FIG. 11.

FIGS. 1 and 2 show a data storage device 2 of a first embodiment of the present invention. The data storage device 2 includes a plurality of stacked layers 4 of memory cells 6, each of which includes a first magnetic layer 5 formed from a suitable material such as conventional NiFe alloy, CoFeB alloy or related ternary alloys. The first magnetic layer 5 has a widened end portion 8 and an elongate curved portion 10 which extends from the end portion 8 and defines an aperture 12. First electrical conductors 14 pass through the apertures 12 in one of the memory cells 6 of each of the layers 4, and the memory cells 6 of each layer 4 are arranged in rows. Second electrical conductors 16 in the form of lithographically patterned wires connect the memory cells 6 of the rows of cells 6 in each layer 4. Each of the layers 4 comprises a substrate 18 on which the second conductors 16 are arranged generally parallel to each other, and to which the widened end portions 8 of the first magnetic layers 5 of the memory cells 6 are mounted in sufficient proximity to enable magnetic fields generated by electrical currents in the second electrical conductors 16 to penetrate the adjacent first magnetic layers 5.

As shown in FIG. 3, each of the memory cells 6 is formed in a three-layer structure comprising the first magnetic layer 5 and a second magnetic layer 20, separated from the first magnetic layer 5 by means of an insulating layer 22. The second magnetic layer 20 functions as a reference layer and its function will be described in greater detail below.

As shown in greater detail in FIGS. 4 and 5, which show two embodiments of a first magnetic layer 5 for use in a two-state memory cell 6, the first magnetic layer 5 has widened end portion 8 and elongate curved portion 10. The widened end portion 8 serves to generate magnetic domain walls by means of reversal of the magnetic field in the widened end portion 8 at a lower magnetic field strength than that needed to reverse the magnetisation of the narrower elongate curved portion 10. The elongate curved portion 10 and end portion 8 are formed from a magnetic material which can be magnetised by means of suitable magnetic fields generated by the adjacent first electrical conductor 14 in cooperation with the adjacent second electrical conductor 16.

In the embodiment of FIG. 5, the elongate curved portion 10 is a discontinuous annular segment forming part of an arc of a circle, and the widened end portion 8 is tapered. Because the elongate curved portion 10 forms a substantially circular arc, it is located at a substantially constant distance from the adjacent first electrical conductor 14 (FIG. 6). As a result, in order to change the magnetised state of the first magnetic layer 5 of the memory cell 6, a suitable magnetic field is generated by means of the appropriate first 14 and second 16 conductors, which causes a magnetic domain wall to be formed in the end portion 8 and then propagate around the curved portion 10 by means of a circular magnetic field generated by the first electrical conductor 14. Because the elongate curved portion 10 is a substantially constant distance from the adjacent first electrical conductor 14, the geometry of the circular magnetic field generated by the first conductor 14 is closely matched to the geometry of the memory cell 6. This enables the magnetised state of the first magnetic layer 5 to be switched by means of a small magnetic field, which minimises the influence of the magnetic field on memory cells 6 other than the memory cell 6 of interest.

As a result, the memory cells 6 each have two data states (illustrated in FIGS. 6 and 7), which are achieved by means of the direction of magnetisation of the first magnetic layer 5. Depending upon the direction of magnetisation of the first magnetic layer 5, the electrical resistance between the first magnetic layer 5 and the adjacent second magnetic layer 20 changes, as a result of which the state of the data stored in the memory cell 6 can be determined by means of a suitable resistance measuring device 24 (FIG. 3) which will be familiar to persons skilled in the art and will therefore not be described in greater detail herein.

The operation of the data storage device 2 described with reference to FIGS. 1 to 7 will now be described.

In order to write data to a selected memory cells 6 of the data storage device 2, a magnetic domain wall (not shown) is generated in the widened end portion 8 of the selected memory cell 6 by means of a suitable current in the second electrical conductor 16 arranged adjacent the end portion 8 of the memory cell 6. A second magnetic field is then generated by means of the first electrical conductor 14 passing through the aperture 12 defined by the elongate curved portion 10 of the memory cell 6, and the second magnetic field causes the domain wall to propagate around the curved portion 10 from the widened end portion 8 to its distal end. Because the circular geometry of the curved portion 10 of the memory cell 6 is closely matched to the circular magnetic fields generated by the first electrical conductor 14, the energy required to write data to the data cell 6 is minimised, the half select problem, in which cells adjacent to the memory cell 6 to which data is to be written are also influenced, is minimised. In order to read data from a selected memory cell 6 of the storage device 2, the electrical resistance between the first magnetic layer 5 of the data cell 6 and the corresponding second magnetic layer 22 is measured by means of the resistance measuring device 24, the resistance value being dependent upon the data state.

FIGS. 8 and 9 show a data storage device 102 of a second embodiment of the invention, in which parts common to the embodiment of FIGS. 1 and 2 are denoted by like reference numerals but increased by 100. The device 102 of FIGS. 8 and 9 differs from that of FIGS. 1 and 2 in that the memory cells 106 of each layer 104 are arranged in a hexagonal array. This provides the advantage of closer packing of the data cells 106, as a result of which the data storage capacity of the device 102 can be increased.

FIGS. 10 and 11, which correspond to FIGS. 4 and 5 respectively, show two further embodiments of the data cells 206, in which parts common to the embodiments of FIGS. 4 and 5 are denoted by like reference numerals but increased by 200 and in which more than two data states exist. The memory cells 206 FIGS. 10 and 11 differs from those of FIGS. 4 and 5 respectively in that domain wall pinning sites in the form of notches 230 in opposite sides of elongate curved portion 210 of the first magnetic layer 205 are provided.

As a result, a magnetic domain wall (not shown) generated in the widened end portion 208 of a memory cell 206 is propagated through the curved portion 210 of the memory cell 206, in a manner similar to the embodiment of FIGS. 4 and 5, until it is pinned by the appropriate notches 230. By choosing appropriate combinations of magnetic field and direction, the type (i.e. chirality) of the magnetic domain wall can be selectively generated and propagated along the curved portion 210 of the memory cell 206 and is either passed or pinned by the notch 230 of the appropriate type. As shown in greater detail in FIG. 12, as a result, the memory cell 206 of FIG. 11 has six data states instead of two, and the electrical resistance of each data state can be measured with sufficient accuracy to enable the data state of the cell to be determined. As a result, the data storage density of the device incorporating the memory cell 206 can be significantly increased.

It will be appreciated by person skilled in the art that the above embodiments have been described by way of example only, and not in any limitative sense, and that various alterations and modifications are possible without departure from the scope of the invention as defined by the appended claims.

1. A data storage device comprising:
at least one memory cell comprising at least one respective first magnetic layer including at least one elongate curved portion having respective first and second ends;
at least one second magnetic layer, wherein at least one said first magnetic layer is adapted to be selectively magnetised to adopt one of a plurality of possible magnetised states, wherein the electrical resistance between said first magnetic layer and at least one said second magnetic layer has a magnitude dependent upon the magnetised state of said first magnetic layer; and
at least one switching device adapted to cause at least one said first magnetic layer to switch between magnetised states thereof.

2. A data storage device according to claim 1, wherein at least one said elongate curved portion is partially annular.

3. A data storage device according to claim 1, wherein at least one said first magnetic layer is adapted to be magnetised such that at least one said curved portion thereof is magnetised predominately along a single direction in at least one said magnetised state thereof.

4. A data storage device according to claim 1, wherein at least one said elongate curved portion is adapted to be magnetised such that said curved portion includes (i) a plurality of regions, wherein the regions of each pair of adjacent said regions are magnetised predominately along different directions and are separated by a respective magnetic domain wall, and (ii) at least one first structural feature adapted to prevent propagation of at least one said magnetic domain wall of a first type past said first structural feature.

5. A data storage device according to claim 4, wherein at least one said elongate curved portion is adapted to be magnetised such that said curved portion includes (iii) at least one second structural feature adapted to prevent propagation of at least one said magnetic domain wall of a second type past said second structural feature.

6. A data storage device according to claim 5, wherein at least one said second structural feature is a notch in or protrusion on the corresponding said elongate curved portion.

7. A data storage device according to claim 4, wherein at least one said first structural feature is a notch in or protrusion in the corresponding said elongate curved portion.

8. A data storage device according to claim 4, wherein at least one said first and/or second structural feature is located on an edge of a corresponding said elongate curved portion.

9. A data storage device according to claim 1, wherein at least one said first magnetic layer may include an end portion having larger width than the adjacent said elongate curved portion.

10. A data storage device according to claim 1, wherein said switching means comprises at least one first electrical conductor adapted to generate at least one first magnetic field and passing through at least one said memory cell and at least one second electrical conductor adapted to generate at least one second magnetic field and arranged adjacent at least one said memory cell.

11. A data storage device according to claim 10, wherein at least one said first electrical conductor is substantially surrounded by said elongate curved portion of at least one said memory cell.

12. A data storage device according to claim 1, comprising at least one array of said memory cells.

13. A data storage device according to claim 12, wherein at least one said array includes at least one said second conductor arranged adjacent a plurality of said memory cells of said array such that at least one said second magnetic field interacts with at least one said first magnetic field generated by at least one said first conductor to change the magnetised state of a said elongate curved portion.

14. A data storage device according to claim 10, further comprising a plurality of said arrays, wherein at least one said first conductor extends through a plurality of arrays.

15. A data storage device according to claim 12, wherein a plurality of said memory cells of at least one said array are arranged in a substantially hexagonal formation.

16. A data storage device according to claim 1, further comprising means for measuring electrical resistance between at least one said first magnetic layer and a said second magnetic layer.

17. A data storage device according to claim 11, further comprising a plurality of said arrays, wherein at least one said first conductor extends through a plurality of arrays.

18. A data storage device according to claim 12, further comprising a plurality of said arrays, wherein at least one said first conductor extends through a plurality of arrays.
